(19) United States
(12) Patent Application Publication
(10) Pub. No.: US 2006/0060952 A1
(43) Pub. Date: Mar. 23, 2006

(54) Heat spreader for non-uniform power dissipation

(76) Inventors: Tsorng-Dih Yuan, Hopewell Junction, NY (US); Hsin-Yu Pan, Taipei (TW)

Correspondence Address: DUANE MORRIS LLP;IP DEPARTMENT (TSMC), 30 SOUTH 17TH STREET, PHILADELPHIA, PA, 19103-4196, US

(21) Appl. No.: 10/947,593

(22) Filed: Sep. 22, 2004

(51) Int. Cl. H01L 23/495; H01L 23/34

(52) U.S. Cl. 257/675; 257/706

(57) ABSTRACT

A heat spreader has first and second regions. The second region lies substantially in a plane. At least a portion of the first region of the heat spreader has an out-of-plane dimension greater than an out-of-plane dimension of the second region. The heat spreader is sized and shaped to be placed with the first region of the heat spreader proximate to a first region of a semiconductor die that dissipates more power than a second region of the die during operation.

### FIELD OF THE INVENTION

The present invention relates to thermal control of electronics generally and more specifically to heat spreaders.

### BACKGROUND

Thermal control of electronic systems is important to make sure that the systems can perform properly for their specified life cycles. If solid state devices are permitted to exceed their maximum allowable operating temperatures, equipment life may be drastically reduced.

The two main mechanisms for thermal control in terrestrial electronics are convection and conduction. Convection uses air flow around a component to remove heat from the component. A heat sink including a plurality of fins may be used to increase the heat removal rate. Conduction spreads the heat energy across the device (chip, package, circuit board, or the like.). Heat spreaders are frequently used to enhance conduction, to provide a more uniform temperature distribution across a device. A heat spreader typically includes a high conductivity thermal pad, made of a material such as copper or aluminum.

Heat spreaders have been used within packages, such as flip chip ball grid array (FC-BGA) packages. FIGS. 1 and 2 show two conventional FC-BGA packages including heat spreaders therein. Heat spreaders can be provided at a low cost using a simple fabrication process. Typically, heat spreaders can be formed by extrusion or stamping from the raw copper or aluminum.

FIG. 1 shows a conventional FC-BGA package 100. The package includes a package substrate 104, to which an integrated circuit die 102 is flip-chip bonded. The die 102 is positioned with its active face facing the package substrate 104, and a plurality of solder balls 106 on the die are reflowed to form electrical and mechanical connections. The space between the die 102 and substrate 104 is flushed, and an underfill 108 is applied to prevent loss of contact during thermal cycling. The one-piece heat spreader 110 is interfaced to the rear surface of the die 102 and to the substrate 104 using a thermal interface material 114, such as an adhesive, a conductive adhesive such as a silver filled epoxy, thermal grease, solder or a phase change material. The substrate 104 has a plurality of solder balls 116, for forming the mechanical and electrical connection between the package 100 and a printed circuit board (PCB), not shown. The heat spreader 110 spreads the heat energy of the die 102 across the surface of the package, reducing the peak temperature. The heat spreader can also form the top half of the package, thus performing a dual function.

FIG. 2 shows another conventional FC-BGA package 200, wherein like items are indicated by reference numerals having the same value as in FIG. 1, increased by 100. Thus, the die 202, package substrate 204, solder balls 206 and 216, and underfill 208 can be the same as corresponding items 102, 104, 106, 116 and 108 described above with reference to FIG. 1, and a description of these items is not repeated. The two piece heat spreader 210, 212 has an advantage that the stiffener ring portion 210 can be applied to the substrate 204 before the substrate 204 is baked. Thus, the ring 210 can prevent warpage of the substrate 104 during baking, which might otherwise interfere with the bond between the solder balls 206 and the substrate 204. After the ring 210 is bonded to the substrate 204, the assembly of package 200 proceeds in a similar fashion to that described above with reference to FIG. 1. After the underfill 208 is applied, the top 212 of the heat spreader is bonded to the ring portion 210 of the heat spreader. Then, the solder balls 216 are applied as described above.

For high power applications, conventional heat spreaders are limited in meeting both thermal performance and reliability specifications. Non-uniform power distribution and density can strongly affect thermal control of junctions and cause failure of chip functionality. When power is non-uniform and power density is high, existing methods do not have sufficient thermal conductivity and surface contact area to achieve thermal performance and are not able to address the hot spot issue. An improved heat spreader is desired.

### SUMMARY OF THE INVENTION

In some embodiments, a heat spreader has first and second regions. The second region lies substantially in a plane. At least a portion of the first region of the heat spreader has an out-of-plane dimension greater than an out-of-plane dimension of the second region. The heat spreader is sized and shaped to be placed with the first region of the heat spreader proximate to a first region of a semiconductor die that dissipates more power than a second region of the die distal from the first region die during operation.

In some embodiments, a package comprises a semiconductor die and a heat spreader. The semiconductor die has first and second regions. The first region dissipates more power than the second region during operation. The die has a surface in a plane. The heat spreader has first and second regions. The first region of the heat spreader is proximate to the first region of the die. The second region of the heat spreader is distal from the first region of the die. At least a portion of the first region of the heat spreader has an out-of-plane dimension greater than an out-of-plane dimension of the second region of the heat spreader.

In some embodiments, a packaging method comprises providing a semiconductor die having first and second regions, and coupling a heat spreader to the die. The first region dissipates more power than the second region during operation. The heat spreader has first and second regions. The first region of the heat spreader is proximate to the first region of the die. The die has a surface in a plane. At least a portion of the first region of the heat spreader has an out-of-plane dimension greater than an out-of-plane dimension of the second region.

### BRIEF DESCRIPTION OF THE DRAWINGS

FIGS. 1 and 2 are side cross sectional views of packages including conventional heat spreaders.

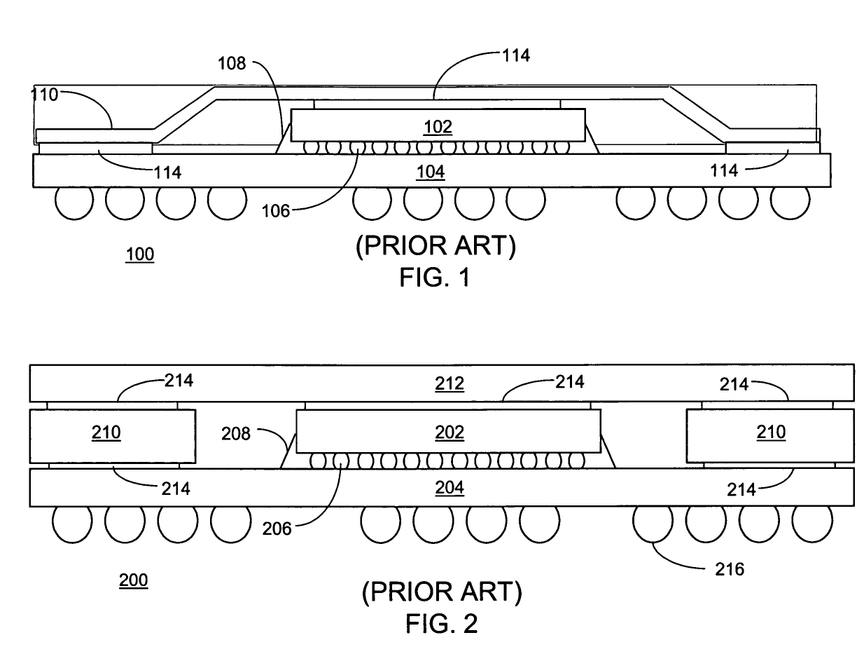

FIG. 3 is an exploded isometric view showing a portion of an exemplary package.

FIGS. 4-6 are side cross sectional views of three variations of heat spreaders according to an exemplary embodiment.

FIGS. 7 and 8 are side cross sectional views of packages including the exemplary heat spreader of FIGS. 3 and 6.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

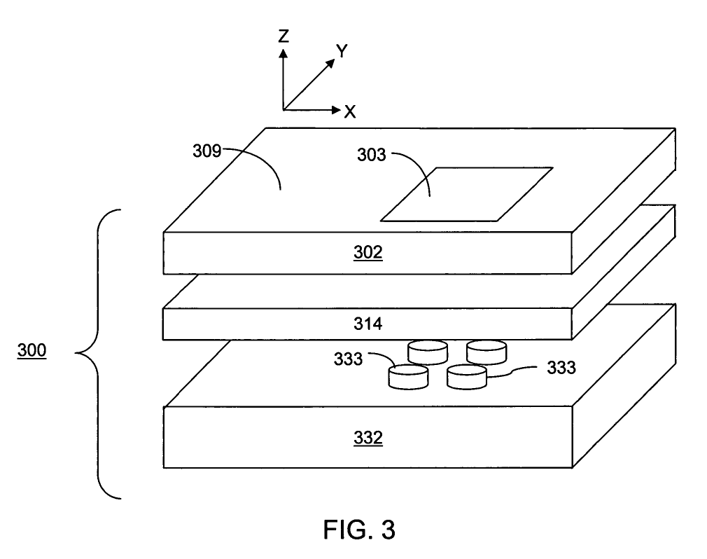

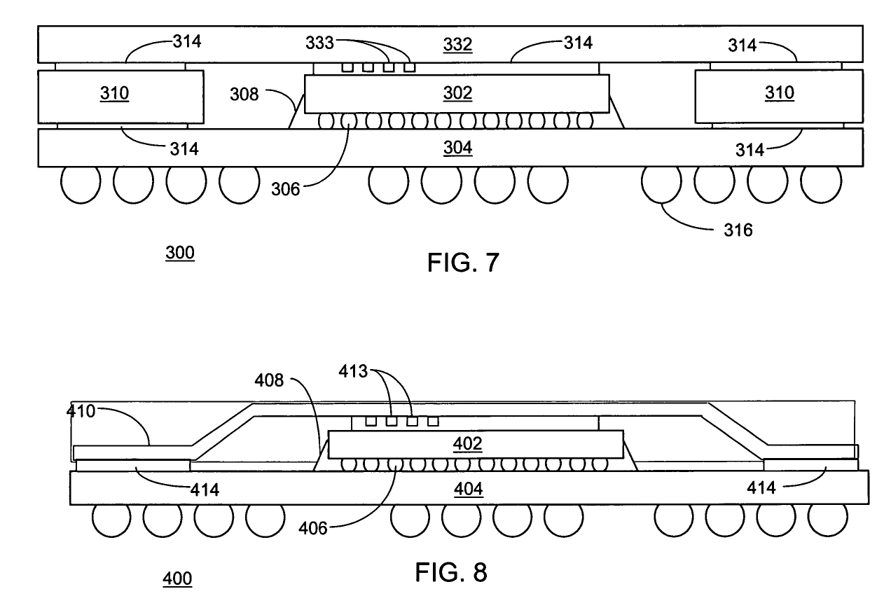

FIGS. 3, 6 and 7 show an exemplary embodiment of a package 300. The package 300 comprises a semiconductor die 302 and a heat spreader 332. FIG. 7 is a side cross sectional view of the package 300. FIG. 3 is an exploded isometric view of a portion of the package 300. FIG. 6 is a side cross sectional view of the heatspreader 332.

The package 300 includes a package substrate 304, to which the heat spreader stiffener ring 310 is bonded (e.g., by solder or conductive adhesive) before baking, preventing substrate warpage. One preferred thermally conductive material is a conductive adhesive material, such as a silver filled epoxy. In the example, the substrate 302 is an organic substrate, such as a glass/epoxy substrate. The substrate may have a plurality of levels, with electrical paths between layers provided by interconnect vias (not shown). The die 302 is positioned with its active face facing the package substrate 304, and a plurality of solder balls 306 on the die are reflowed to form electrical and mechanical connections, so that the integrated circuit die 302 is flip-chip bonded to the substrate 304. The space between the die 302 and substrate 304 is flushed with a solvent, such as water, and an underfill 308 is applied to prevent loss of contact during thermal cycling. The underfill material 308 may be an epoxy or other known underfill material. The top section 332 of the heat spreader is interfaced to the rear surface of the die 302 using a thermal interface material 314, such as an adhesive, a conductive adhesive such as a silver filled epoxy, thermal grease, solder or a phase change material. The preferred material 314 for connecting the top of the heatspreader to the rear surface of the die depends on the chip power levels and therefore, epoxy, thermal grease and phase change material are all preferred for their respective power levels. The top section 332 of the heat spreader is also bonded to the ring 310 of the heat spreader using solder or a conductive adhesive such as a silver filled epoxy. The substrate 104 has a plurality of solder balls 116, for forming the mechanical and electrical connection between the package 100 and a printed circuit board (PCB), not shown.

The die 302 has a first region 303 and a second region 309 (best seen in FIG. 3). The first region 303 may be a single contiguous area or a plurality of non-contiguous areas. Similarly, the second region 309 may be a single contiguous area or a plurality of non-contiguous areas. The first region 303 dissipates more power than the second region 309 during operation. For example, the first region 303 may include circuitry, such as active and/or passive devices. The die 302 has a major surface in the X-Y plane.

The heat spreader 332 has a first region 335 and a second region 331. The first region 335 of the heat spreader 332 is proximate to the first region 303 of the die 302. The second region 331 of the heat spreader 332 is distal from the first region 303 of the die 302. At least a portion 333 of the first region 335 of the heat spreader 332 has an out-of-plane dimension T1 (in the Z direction) greater than an out-of-plane dimension T2 of the second region 331.

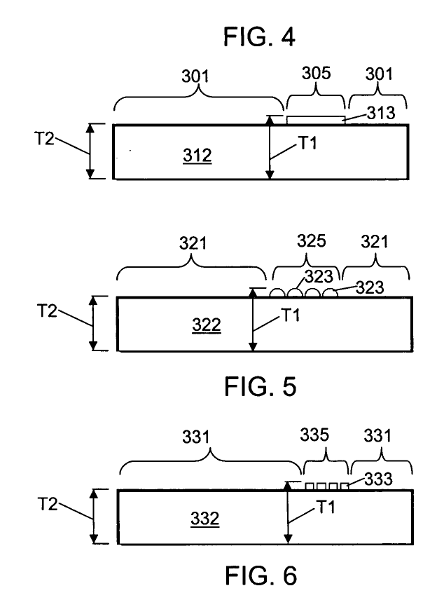

The portion 333 of the first region may be a single contiguous area (as discussed below with reference to FIG. 4) or the first region may include a plurality of non-contiguous areas 333, as shown in FIG. 3. In the embodiment of FIGS. 3, 6, and 7, the portion 333 of the first region 335 comprises a plurality of protrusions on a side of the heat spreader 332 facing the die 302. Although the protrusions 333 in FIG. 3 are substantially cylindrical, other shapes may be used.

A layer 314 of a thermal interface material is provided between the die 302 and the heat spreader 332. The at least one protrusion 333 protrudes at least partially through the thermal interface material. The protrusions 333 provide a low-thermal-resistance path between the heat sink 332 and the hot spot in the first region 303 of the die 302. This increases the rate at which energy can be conducted between the hot spot and the heat spreader 332, and decreases the temperature difference between the hot spot and the heat spreader, for any given ambient temperature and amount of power dissipated by the die 302.

One of ordinary skill in the art understands that the improvement in the thermal resistance between the heat spreader and die is greatest if the protrusion(s) 333 extend(s) as close as possible to the rear face of the die 302. Preferably, the length of the protrusion(s) 333 is selected to be sufficiently short to leave a small gap between the protrusions 333 and the die 302, to accommodate any expected thermal expansion or stress deflection in the die 302. In some embodiments, the protrusion(s) 333 may extend all the way to the rear of the die.

In some embodiments, the heat spreader 310, 332 is made of copper. Heat spreaders as described above can provide the desired metal columns or bumps with high thermal conductivity (such as copper with conductivity K=395 w/m-k and Cu C with K=350 W/m-k). In other embodiments, other high conductivity materials may be used for the heat spreader, where the material has a coefficient of thermal expansion compatible with that of the die 302. Although a material with a substantially different coefficient of thermal expansion (such as aluminum) could be used for the heatspreader 411, an elastic thermal interface material would then be used to accommodate the expansion of the heatspreader, and still conduct heat well.

FIG. 4 shows a portion of another variation of the heat spreader 312, wherein the the first region 305 of the heat spreader 312 has a substantially constant thickness T1 greater than a thickness T2 of the second region. In the embodiment of FIG. 4, the first region 305 of the heat spreader substantially overlies the first region 303 of the die 302, and has the same shape and size as the first region of the die 302. One of ordinary skill will understand that thermal conduction between the hot spot of the die 302 and the heat spreader 312 is maximized when the first region 305 of the heat spreader 312 is at least as large (in the X-Y plane) as the hot spot. In some embodiments, the first region 305 of the heat spreader 312 is slightly longer or wider (in the X-Y plane) than the hot spot 303. Then heat which fans out into the die can be effectively conducted to the heat spreader 312. In other embodiments, the first region 305 of the heat spreader may be smaller than the hot spot 303.

FIG. 5 shows another variation of the heat spreader 322, wherein the first region 325 of the heat spreader includes a plurality of bumps 323 thereon. In FIG. 5, the bumps 323 are approximately hemispherical. One of ordinary skill will understand that other bump shapes may also be used.

Although exemplary shapes are shown for the protrusions 323, 333 in the first region of the heat spreader, a variety of other shapes may be used, including, but not limited to, a prism having any desired number of sides, a pyramid having any desired number of sides, a cone, a frustum, an elliptic paraboloid, an elliptic cylinder, or other arbitrary three-dimensional shape.

FIG. 8 shows another variation of a package 400 including a one-piece heat spreader 410 having projections 413 thereon. The other elements of the package 400, including die 402, substrate 404, solder balls 406 and 416, underfill 408, and thermal interface material 414 may be the same as described above with reference to the elements of FIG. 7, with the reference numerals increased by 100. The projections 413 perform the same function as described above with respect to projections 333 in FIG. 7.

Although two packages 300 and 400 having two heat spreader configurations are described above, the invention is not limited to these heat spreader configurations. A region having a greater out-of-plane dimension, such as a thicker region (e.g., 305 as shown in FIG. 4), or protrusions (e.g., 323 or 333 as shown in FIGS. 7 and 8) can be added to heat spreaders of a variety of other configurations.

Heat spreaders as described above may be fabricated using conventional technologies, such as molding, stamping, or extrusion.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A package comprising:
a semiconductor die having first and second regions, the first region dissipating more power than the second region during operation, the die having a surface in a plane; and
a heat spreader having first and second regions, the first region of the heat spreader proximate to the first region of the die, the second region of the heat spreader distal from the first region of the die, at least a portion of the first region of the heat spreader having an out-of-plane dimension greater than an out-of-plane dimension of the second region of the heat spreader.

2. The package of claim 1, wherein the portion of the first region of the heat spreader has at least one protrusion on a side of the heat spreader facing the die.

3. The package of claim 2, further comprising a layer of a thermal interface material between the die and the heat spreader, wherein the at least one protrusion protrudes at least partially through the thermal interface material.

4. The package of claim 2, wherein the first region of the heat spreader includes a plurality of protrusions on a side of the heat spreader facing the die.

5. The package of claim 4, wherein the protrusions are substantially cylindrical.

6. The package of claim 1, wherein the first region of the heat spreader substantially overlies the first region of the die.

7. The package of claim 6, wherein the first region of the heat spreader has a substantially constant thickness greater than a thickness of the second region.

8. The package of claim 1, wherein the first region of the heat spreader includes a plurality of bumps thereon.

9. The package of claim 8, wherein the bumps are approximately hemispherical.

10. The package of claim 1, further comprising:
a package substrate to which the die is flip-chip mounted; and
a layer of a thermal interface material between the die and the heat spreader,
wherein the portion of the first region has a plurality of protrusions on a side of the heat spreader facing the die, the plurality of protrusions protruding at least partially through the thermal interface material towards the die, the protrusions having a shape that is substantially cylindrical or substantially hemispherical.

11. A packaging method, comprising:
providing a semiconductor die having first and second regions, the first region dissipating more power than the second region during operation, the die having a surface in a plane; and
coupling a heat spreader to the die, the heat spreader having first and second regions, the first region of the heat spreader proximate to the first region of the die, the second region of the heat spreader distal from the first region of the die, at least a portion of the first region of the heat spreader having an out-of-plane dimension greater than an out-of-plane dimension of the second region of the heat spreader.

12. The method of claim 11, wherein the portion of the first region of the heat spreader has at least one protrusion, and the method includes orienting the heat spreader with the protrusion facing the die.

13. The method of claim 12, further comprising providing a layer of a thermal interface material between the die and the heat spreader, and the coupling step includes placing the heat spreader so that the at least one protrusion protrudes at least partially through the thermal interface material.

14. The method of claim 12, wherein the first region of the heat spreader includes a plurality of protrusions on a side of the heat spreader facing the die.

15. The method of claim 14, wherein the protrusions are substantially cylindrical.

16. The method of claim 11, further comprising placing the heat spreader so that the first region of the heat spreader substantially overlies the first region of the die.

17. The method of claim 16, wherein the first region of the heat spreader has a substantially constant thickness greater than a thickness of the second region.

18. The method of claim 11, wherein the first region of the heat spreader includes a plurality of bumps thereon.

19. The method of claim 18, wherein the bumps are approximately hemispherical.

20. A heat spreader having first and second regions, the second region lying substantially in a plane, at least a portion of the first region of the heat spreader having an out-of-plane dimension greater than an out-of-plane dimension of the second region, the heat spreader sized and shaped to be placed with the first region of the heat spreader proximate to a first region of a semiconductor die that dissipates more power than a second region of the die distal from the first region of the die during operation.

21. The heat spreader of claim 20, wherein the portion of the first region has at least one protrusion on a side of the heat spreader adapted to face the die.

22. The heat spreader of claim 21, wherein the first region of the heat spreader includes a plurality of protrusions on a side of the heat spreader adapted to face the die.

23. The heat spreader of claim 22, wherein the protrusions are substantially cylindrical.

24. The heat spreader of claim 20, wherein the first region of the heat spreader has a size and shape approximately the same as the first region of the die, and the heat spreader is sized and shaped so that, when the heat spreader is coupled to the die, the first region of the heat spreader is aligned with the first region of the die.

25. The heat spreader of claim 24, wherein the first region of the heat spreader has a substantially constant thickness greater than a thickness of the second region.

26. The heat spreader of claim 20, wherein the first region of the heat spreader includes a plurality of bumps thereon.

27. The heat spreader of claim 26, wherein the bumps are approximately hemispherical.
